(19) United States
(12) Patent Application Publication
(10) Pub. No.: US 2025/0380544 A1
(43) Pub. Date: Dec. 11, 2025

(54) METHOD OF MANUFACTURING DISPLAY DEVICE, ELECTRONIC DEVICE INCLUDING THE DISPLAY DEVICE AND VISUAL INSPECTION APPARATUS

(71) Applicant: Samsung Display Co., LTD., Yongin-si (KR)

(72) Inventor: Jeong Moon LEE, Yongin-si (KR)

(21) Appl. No.: 19/025,775

(22) Filed: Jan. 16, 2025

(30) Foreign Application Priority Data
Jun. 7, 2024 (KR) 10-2024-0074229

(51) Int. Cl. H10H 29/01; H01L 25/075; H10H 29/03; H10H 29/14; H10H 29/80

(52) U.S. Cl. CPC H10H 29/032; H01L 25/0753; H10H 29/03; H10H 29/14; H10H 29/8323

(57) ABSTRACT

In a method of manufacturing a display device, the method includes providing a carrier module including a carrier wafer and light-emitting elements, forming a planarization layer between the light-emitting elements, forming a transparent electrode layer on the planarization layer, inspecting the light-emitting elements, and removing the planarization layer and the transparent electrode layer.

### CROSS-REFERENCE TO RELATED APPLICATION

The present application claims priority to, and the benefit of, Korean patent application No. 10-2024-0074229, filed on Jun. 7, 2024, in the Korean Intellectual Property Office, the entire disclosure of which is incorporated herein by reference.

### BACKGROUND

### 1. Field

The present disclosure generally relates to a method of manufacturing a display device, an electronic device including the display device and a visual inspection apparatus.

### 2. Description of the Related Art

Recently, as interest in information displays is increased, research and development of display devices have been continuously conducted.

A display device may include a light-emitting element. To manufacture the display device, a process of manufacturing a light-emitting element, and transferring the light-emitting element onto a backplane layer of the display device, or the like, may be performed.

To ensure uniformity of the quality of the display device, an inspection process of the light-emitting element may be performed during a manufacturing process of the display device.

To perform the inspection process, it may be suitable that an electrical signal for light emission should be supplied to the light-emitting element. Therefore, it may be difficult for the inspection process to be performed before the light-emitting element is transferred onto the backplane layer.

The above information disclosed in this Related Art section is only for enhancement of understanding of the background of the disclosure, and therefore may contain information that does not form the prior art that is already known in this country to a person of ordinary skill in the art.

### SUMMARY

Embodiments provide a method of manufacturing a display device and a display device, in which a defect rate of a light-emitting element is decreased, so that process efficiency can be improved.

Embodiments also provide a method of manufacturing a display device and a display device, in which an inspection process of a light-emitting element can be suitably performed.

In accordance with an aspect of the present disclosure, there is provided a method of manufacturing a display device, the method including providing a carrier module including a carrier wafer and light-emitting elements, forming a planarization layer between the light-emitting elements, forming a transparent electrode layer on the planarization layer, inspecting the light-emitting elements, and removing the planarization layer and the transparent electrode layer.

The providing of the carrier module may include forming a photoresist layer at an upper end of the light-emitting elements, forming a protective layer on the light-emitting elements, and removing the photoresist layer.

The protective layer may include a dielectric material.

The removing of the planarization layer may include removing at least a portion of the planarization layer such that an upper end of the light-emitting elements is exposed.

The planarization layer may include photosensitive polyimide.

The forming of the transparent electrode layer on the planarization layer may include using an ink-jet printing process.

The transparent electrode layer may contact the upper end of the light-emitting elements.

The transparent electrode layer may include a carbon nano tube or a silver nano wire.

The inspecting of the light-emitting elements may include supplying a voltage to the carrier wafer and the transparent electrode layer such that power is supplied to the light-emitting elements.

The inspecting of the light-emitting elements may include acquiring visual information including mapping information of the light-emitting elements and indicating that at least some of the light-emitting elements emit light.

The removing of the planarization layer and the transparent electrode layer may include removing at least a portion of the planarization layer and the transparent electrode layer after the inspecting.

The removing of the at least the portion of the planarization layer and the transparent electrode layer may include a Chemical Mechanical Polishing (CMP) process.

The removing of the planarization layer and the transparent electrode layer may further include removing a remaining portion of the planarization layer.

The removing of the remaining portion of the planarization layer may include an etching process.

The removing of the remaining portion of the planarization layer may include removing the transparent electrode layer by irradiating laser onto the transparent electrode layer.

The method may further include repairing at least one of the light-emitting elements, and transferring the light-emitting elements onto a pixel circuit layer.

The transferring of the light-emitting elements onto the pixel circuit layer may include removing the carrier wafer, and placing the light-emitting elements on the pixel circuit layer.

In accordance with another aspect of the present disclosure, there is provided a display device manufactured by the method.

The light-emitting elements may include a micro light-emitting diode (LED).

The display device may further include a visual inspection apparatus for the inspecting the light-emitting elements, the visual inspection apparatus being above the carrier module to acquire visual information through light emitted by at least some of the light-emitting elements.

### BRIEF DESCRIPTION OF THE DRAWINGS

Embodiments will now be described more fully hereinafter with reference to the accompanying drawings, although they may be embodied in different forms, and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. Like reference numerals refer to like elements throughout.

FIG. 1 is a schematic plan view illustrating a display device in accordance with one or more embodiments of the present disclosure.

FIG. 2 is a schematic sectional view illustrating the display device in accordance with one or more embodiments of the present disclosure.

FIG. 3 is a flowchart illustrating a method of manufacturing a display device in accordance with one or more embodiments of the present disclosure.

FIG. 4 is a flowchart illustrating one or more embodiments of S100 shown in FIG. 3.

FIGS. 5 to 12 are schematic views illustrating process operations of an operation of providing a carrier module in accordance with one or more embodiments of the present disclosure.

FIGS. 13 and 14 are schematic views illustrating process operations of an operation of forming a planarization layer in accordance with one or more embodiments of the present disclosure.

FIG. 15 is a view illustrating an operation of forming a transparent electrode layer in accordance with one or more embodiments of the present disclosure.

FIGS. 16 and 17 are schematic view illustrating process operations of an operation of inspecting light-emitting elements in accordance with one or more embodiments of the present disclosure.

FIG. 18 is a plan view illustrating a state in which the carrier module is viewed on a plane.

FIGS. 19 and 20 a schematic views illustrating process operations of an operation of removing the planarization layer and the transparent electrode layer in accordance with one or more embodiments of the present disclosure.

FIG. 21 is a view illustrating an operation of transferring the light-emitting elements in accordance with one or more embodiments of the present disclosure.

FIG. 22 is a block diagram of an electronic device according to an embodiment.

FIG. 23 shows schematic views of various embodiments of an electronic device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

The phrase “in a plan view” means when an object portion is viewed from above, and the phrase “in a schematic cross-sectional view” means when a schematic cross-section taken by vertically cutting an object portion is viewed from the side.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

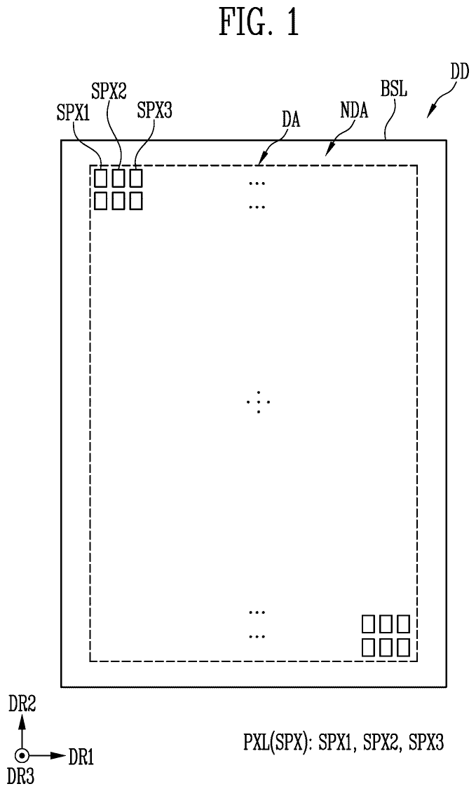

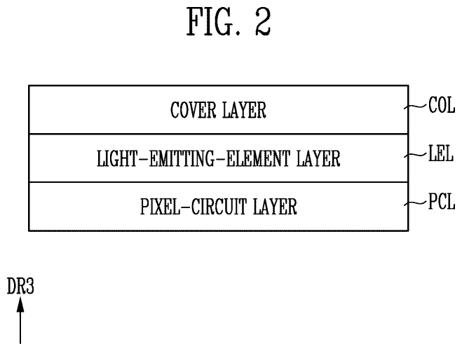

A display device DD in accordance with one or more embodiments of the present disclosure will be described with reference to FIGS. 1 and 2.

FIG. 1 is a schematic plan view illustrating a display device in accordance with one or more embodiments of the present disclosure.

Referring to FIG. 1, the display device DD may include a base layer BSL, and pixels PXL located on the base layer BSL (as used herein, “located on” may mean “above”). In one or more embodiments, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA (e.g., in plan view).

The base layer BSL may form a base surface of the display device DD. The base layer BSL may be a rigid or flexible substrate or film. For example, the base layer BSL may be a rigid substrate made of glass or tempered glass, a flexible substrate (or thin film) made of a plastic or metal material, or at least one insulating layer. However, the material and/or property of the base layer BSL are/is not particularly limited. In one or more embodiments, the base layer BSL may be substantially transparent. The term “substantially transparent” may mean that light can be transmitted with a certain transmittance or more. In one or more other embodiments, the base layer BSL may be translucent or opaque. Also, the base layer BSL may include a reflective material in some embodiments.

The display area DA may mean an area in which the pixels PXL are located. The non-display area NDA may mean an area in which the pixels PXL are not located. The driving circuit, the lines, and the pads, which are connected to the pixels PXL of the display area DA, may be located in the non-display area NDA.

In accordance with one or more embodiments, the pixels PXL (or sub-pixels SPX) may be arranged according to a stripe arrangement structure, a PENTILE™ arrangement structure, or the like (PENTILE™ being a registered trademark of Samsung Display Co., Ltd., Republic of Korea). However, the present disclosure is not limited thereto, and various embodiments may be applied in the present disclosure.

In accordance with one or more embodiments, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form one pixel unit capable of emitting lights of various colors.

For example, each of the first sub-pixel SPX1, the second sub-pixel SPX2, and the third sub-pixel SPX3 may respectively emit light of one color. For example, the first sub-pixel SPX1 may be a red pixel for emitting light of red (e.g., the first color), the second sub-pixel SPX2 may be a green pixel for emitting light of green (e.g., the second color), and the third sub-pixel SPX3 may be a blue pixel for emitting light of blue (e.g., the third color). In accordance with one or more embodiments, a number of second sub-pixels SPX2 may be greater than a number of first sub-pixels SPXL1 and a number of third sub-pixels SPXL3. However, the color, kind, and/or number of first, second, and third sub-pixels SPX1, SPX2, and SPX3 constituting each pixel unit are not limited to any specific example.

FIG. 2 is a schematic sectional view illustrating the display device in accordance with one or more embodiments of the present disclosure.

Referring to FIG. 2, the display device DD may include a pixel circuit layer PCL (e.g., a backplane layer), a light-emitting element layer LEL, and a cover layer COL.

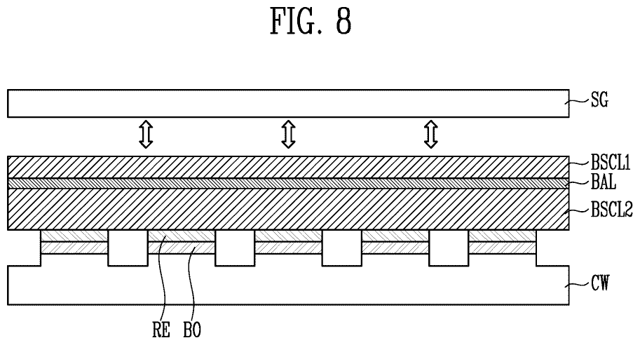

The pixel circuit layer PCL may be a layer including a pixel circuit for driving a pixel PXL formed by the light-emitting element layer LEL (or a light-emitting element LE (see FIG. 8) included in the light-emitting element layer LEL). The pixel circuit layer PCL may include a base layer BSL (see FIG. 1), conductive layers for forming pixel circuits, and insulating layers located on the conductive layers.

The light-emitting element layer LEL may be located on the pixel circuit layer PCL. In some embodiments, the light-emitting element layer LEL may include the light-emitting element LE. In some embodiments, the light-emitting element LE may include an inorganic light-emitting element including an inorganic material. However, the present disclosure is not necessarily limited thereto.

In some embodiments, the light-emitting element LE may have a nano scale size to a micro scale size. For example, the light-emitting element LE may be a micro light-emitting diode (LED). However, the present disclosure is not limited thereto.

The cover layer COL may be located on the light-emitting element layer LEL. The cover layer COL may allow light emitted from the light-emitting element layer LEL to be transmitted therethrough. The cover layer COL may include a window. The cover layer COL may include a structure (e.g., a film, a film stacked structure, or the like) for reducing or preventing external light reflection. However, the present disclosure is not limited thereto.

Meanwhile, an inspection process, which determines whether the light-emitting elements LE included in the display device DD operate normally during a manufacturing process, is thoroughly performed on the light-emitting elements LE, so that a defect rate of the light-emitting elements LE can be decreased. Accordingly, a process yield can be improved.

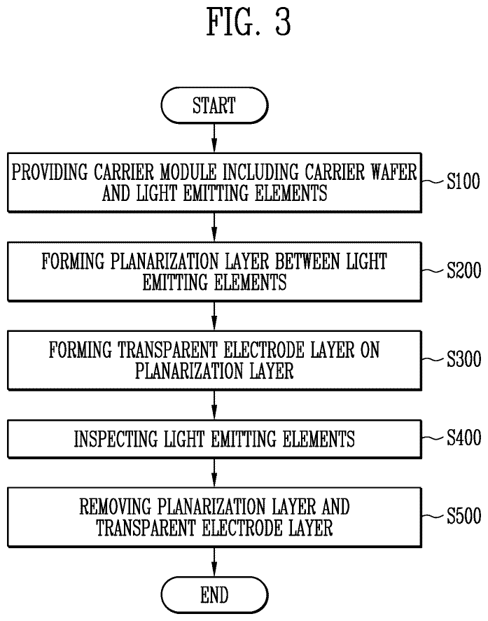

In relation to this, a method of manufacturing a display device DD including an inspection process on the display device DD will be described with reference to drawings from FIG. 3.

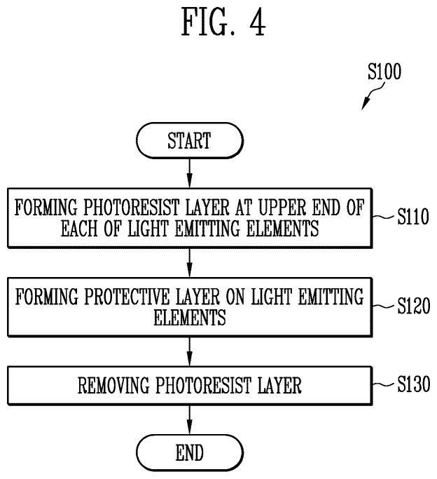

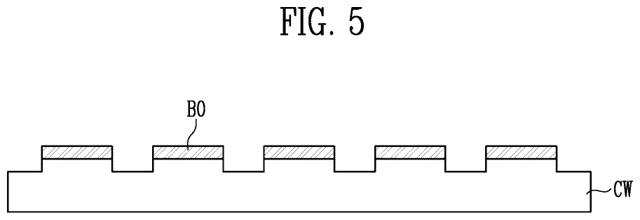

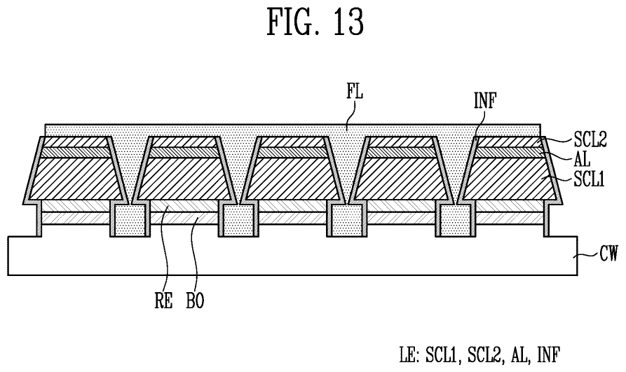

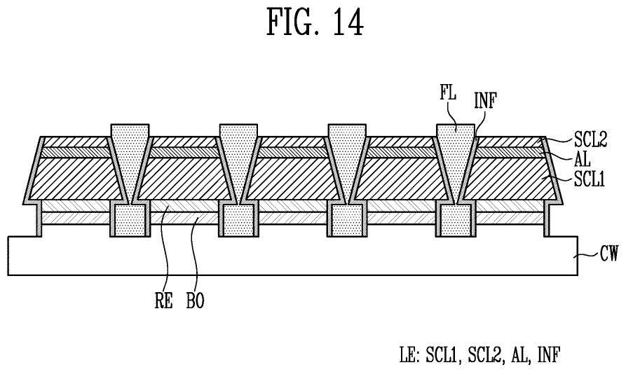

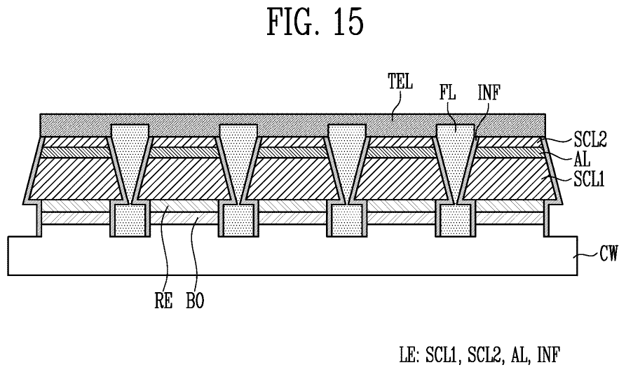

FIG. 3 is a flowchart illustrating a method of manufacturing a display device in accordance with one or more embodiments of the present disclosure. FIG. 4 is a flowchart illustrating one or more embodiments of S100 shown in FIG. 3. FIGS. 5 to 12 are schematic views illustrating process operations of an operation of providing a carrier module in accordance with one or more embodiments of the present disclosure. FIGS. 13 and 14 are schematic views illustrating process operations of an operation of forming a planarization layer in accordance with one or more embodiments of the present disclosure. FIG. 15 is a view illustrating an operation of forming a transparent electrode layer in accordance with one or more embodiments of the present disclosure.

Referring to FIG. 3, the method of manufacturing the display device DD may include operation S100 of providing a carrier module including a carrier wafer and light-emitting elements, operation S200 of forming a planarization layer between the light-emitting elements, operation S300 of forming a transparent electrode layer on the planarization layer, operation S400 of inspecting the light-emitting elements, and operation S500 of removing the planarization layer and the transparent electrode layer.

Referring to FIG. 4, the operation S100 of providing a carrier module including the carrier wafer and the light-emitting elements may include operation S110 of forming a photoresist layer at an upper end of each of the light-emitting elements, operation S120 of forming a protective layer on the light-emitting elements, and operation S130 of removing the photoresist layer.

Referring to FIGS. 5 to 15, in the operation S100 of providing a carrier module including the carrier wafer and the light-emitting elements, at least one light-emitting element LE may be manufactured, and a carrier module CM may be manufactured as the light-emitting element LE is bonded to a carrier wafer CW.

Referring to FIG. 5, in the operation S100 of providing a carrier module including the carrier wafer and the light-emitting elements, at least one bonding electrode BO may be patterned on the carrier wafer CW.

The carrier wafer CW may be a moving member arbitrarily attached to transfer the light-emitting element LE. The carrier wafer CW may include various materials. In some embodiments, the carrier wafer CW may include silicon (Si). The material of the carrier wafer CW is not particularly limited.

The carrier wafer CW may serve as a path for supplying an electrical signal to the light-emitting element LE for the purpose of an inspection process on the light-emitting element LE. To this end, in some embodiments, the carrier wafer CW may have conductivity.

The bonding electrode BO may be provided to bond the light-emitting element LE and the carrier wafer CW to each other in a subsequent process. The bonding electrode BO may be patterned according to one standard. For example, the bonding electrodes BO may be located to respectively correspond to positions of the light-emitting elements LE individually distinguished from each other.

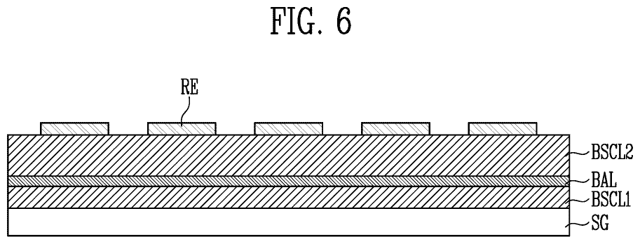

Referring to FIG. 6, in the operation S100 of providing a carrier module including the carrier wafer and the light-emitting elements, semiconductor materials may be sequentially formed on a growth substrate SG, and reflective electrodes RE may be patterned.

The growth substrate SG may be a base plate for growing a target material. For example, the growth substrate SG may be a wafer for epitaxial growth on one material. The growth substrate SG may be a sapphire substrate, and may include aluminum oxide (AlOₓ). However, the present disclosure is not limited thereto.

In this operation, a first base semiconductor layer BSCL1, a base active layer BAL, and a second base semiconductor layer BSCL2 may be sequentially formed (e.g., epitaxially grown) on the growth substrate SG.

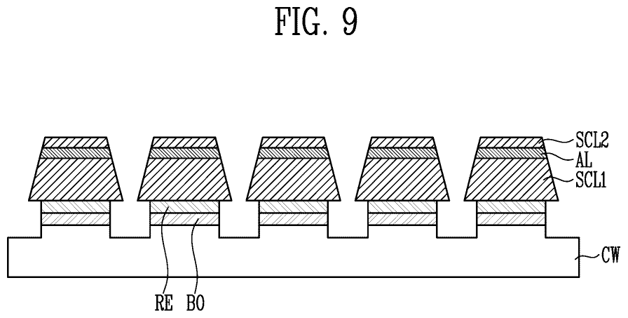

The first base semiconductor layer BSCL1 may include a material for forming a first semiconductor layer SCL1 (see FIG. 9). The base active layer BAL may include a material for forming an active layer AL (see FIG. 9). The second base semiconductor layer BSCL2 may include a material for forming a second semiconductor layer SCL2 (see FIG. 9).

The reflective electrode RE may be provided to be bonded to the bonding electrode BO in a subsequent process. The reflective electrode RE may be patterned according to one standard. For example, the reflective electrodes RE may be located to respectively correspond to positions of the light-emitting elements LE individually distinguished from each other.

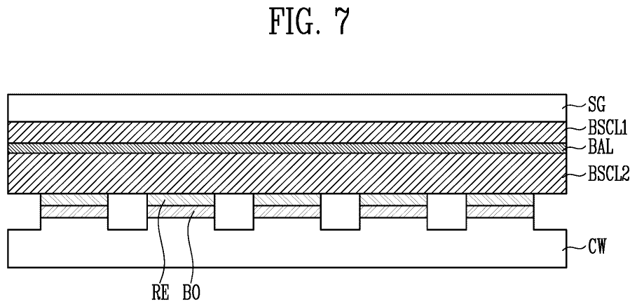

Referring to FIG. 7, in the operation S100 of providing a carrier module including the carrier wafer and the light-emitting elements, the reflective electrode RE and the bonding electrode BO may be bonded to each other, so that the semiconductor layers BSCL1, BAL, and BSCL2 stacked on the growth substrate SG are bonded to the carrier wafer CW.

In accordance with one or more embodiments, after the reflective electrode RE is located on the bonding electrode BO, the bonding electrode BO and the reflective electrode RE may be bonded to each other by applying heat (e.g., by irradiating laser) between the bonding electrode BO and the reflective electrode RE. However, the present disclosure is not limited thereto.

Referring to FIG. 8, in the operation S100 of providing a carrier module including the carrier wafer and the light-emitting elements, the growth substrate SG may be separated.

In accordance with one or more embodiments, the growth substrate SG may be physically spaced apart from the first base semiconductor layer BSCL1. In some embodiments, a laser lift-off process or the like may be used. However, the present disclosure is not limited thereto.

Referring to FIGS. 8 and 9, in the operation S100 of providing a carrier module including the carrier wafer and the light-emitting elements, the semiconductor layers BSCL1, BAL, and BSCL2 may be etched, and the first semiconductor layer SCL1, the active layer AL, and the second semiconductor layer SCL2, which are individually separated from each other, may be provided. Accordingly, the light-emitting element LE including the first semiconductor layer SCL1, the active layer AL, and the second semiconductor layer SCL2 may be provided.

The first semiconductor layer SCL1 may include a semiconductor layer having a type that is different from a type of the second semiconductor layer SCL2. For example, the first semiconductor layer SCL1 may include an N-type semiconductor. The first semiconductor layer SCL1 may include a GaN-based material. For example, the first semiconductor layer SCL1 may include at least one selected from the group consisting of InAlGaN, GaN, AlGaN, and/or InGaN, and may include an N-type semiconductor layer doped with a first conductivity type dopant, such as Si, Ge, and/or Sn.

The active layer AL may be located between the first semiconductor layer SCL1 and the second semiconductor layer SCL2. The active layer AL may include a single-quantum well or multi-quantum well structure.

The active layer AL may include a well layer and a barrier layer, which are used to form a quantum well structure. For example, the active layer AL may include InGaN as the well layer, and may include GaN as the barrier layer.

The second semiconductor layer SCL2 may include a semiconductor layer having a type different from the type of the first semiconductor layer SCL1. For example, the second semiconductor layer SCL2 may include a P-type semiconductor. The second semiconductor layer may include a GaN-based material. For example, the second semiconductor layer SCL2 may include at least one selected from the group consisting of InAlGaN, GaN, AlGaN, and/or InGaN, and may include a P-type semiconductor layer doped with a second conductivity type dopant, such as Ga, B, and/or Mg.

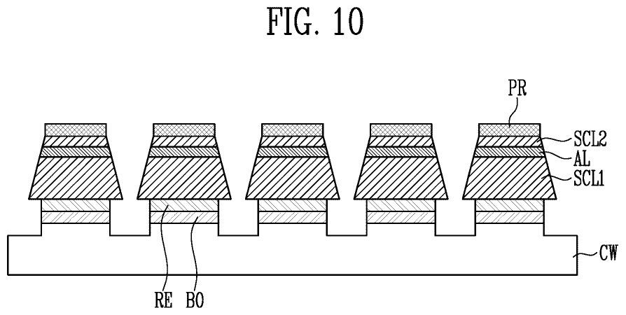

Referring to FIGS. 4 and 10, in the operation S110 of forming the photoresist layer at the upper end of each of the light-emitting elements, a photoresist layer PR may be formed at an upper end of each of the light-emitting elements LE. For example, the photoresist layer PR may be located to be in contact with the second semiconductor layer SCL2. Accordingly, the photoresist layer PR may not expose an upper surface of each of the light-emitting elements LE to the outside.

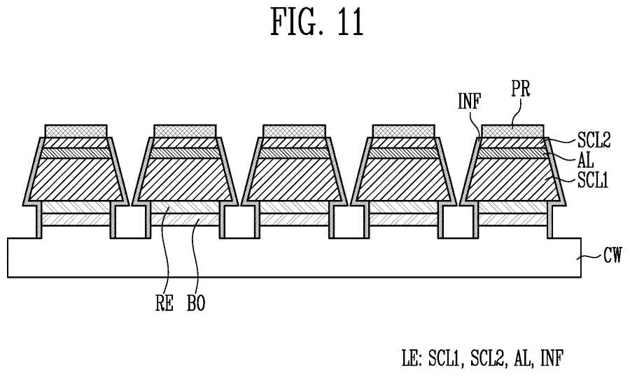

Referring to FIGS. 4 and 11, in the operation S120 of forming the protective layer on the light-emitting elements, a protective layer INF may be formed on the light-emitting elements LE. For example, the protective layer INF may be located on side surfaces of the light-emitting elements LE. The protective layer INF may not be formed on the photoresist layer PR. In some embodiments, the protective layer INF may be made of a dielectric material.

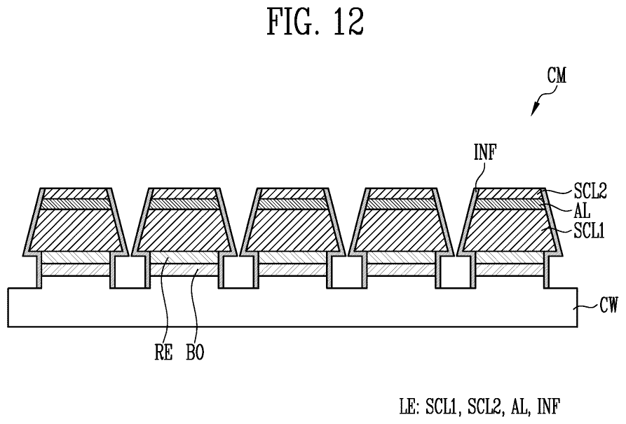

Referring to FIGS. 4 and 12, in the operation S130 of removing the photoresist layer, the photoresist layer PR may be removed. Accordingly, at least a portion of the second semiconductor layer SCL2 may be exposed to the outside.

Accordingly, a carrier module CM may be provided, which includes the carrier wafer CW and the light-emitting elements LE. However, a process operation for manufacturing the carrier module CM is not necessarily limited to the above-described example.

Referring to FIGS. 3, 13, and 14, in the operation S200 of forming the planarization layer between the light-emitting elements, a planarization layer FL may fill spaces spaced apart from each other between the light-emitting elements LE. Accordingly, the planarization layer FL may form a flat layer on the light-emitting element LE. The planarization layer FL may include photosensitive polyimide. However, the present disclosure is not limited thereto.

In some embodiments, the planarization layer FL may have a thickness of about 30 nm (nanometer) from the upper end of each of the light-emitting elements LE. For example, the planarization FL may form a flat layer having a thickness of about 30 nm from an upper surface of the second semiconductor layer SCL2.

In this operation, at least a portion of the planarization layer FL may be removed. For example, a portion of a component of the planarization layer FL, which contacts the second semiconductor layer SCL2, may be removed. Accordingly, the second semiconductor layer SCL2 may be exposed to the outside.

Referring to FIGS. 3 and 15, in the operation S300 of forming the transparent electrode layer on the planarization layer, a transparent electrode layer TEL may be formed over the planarization layer FL and the light-emitting elements LE. At least a portion of the transparent electrode layer TEL may be in contact with the second semiconductor layer SCL2. The transparent electrode layer TEL may cover the planarization layer FL and the second semiconductor layer SCL2.

The transparent electrode layer TEL may not be damaged by heat that may be generated in the light-emitting elements LE. For example, when the transparent electrode layer TEL is made of indium tin oxide, the transparent electrode layer TEL may be relatively weak to heat. On the other hand, in accordance with one or more embodiments of the present disclosure, the transparent electrode layer TEL may be made of a carbon nano tube or a silver nano wire. Accordingly, the transparent electrode layer TEL is not damaged by heat generated in an inspection process of the light-emitting elements LE, which will be described later, and the reliability of the inspection process of the light-emitting elements LE can be relatively improved.

The transparent electrode layer TEL may be formed through an ink-jet process. For example, the transparent electrode layer TEL may be located over the planarization layer FL.

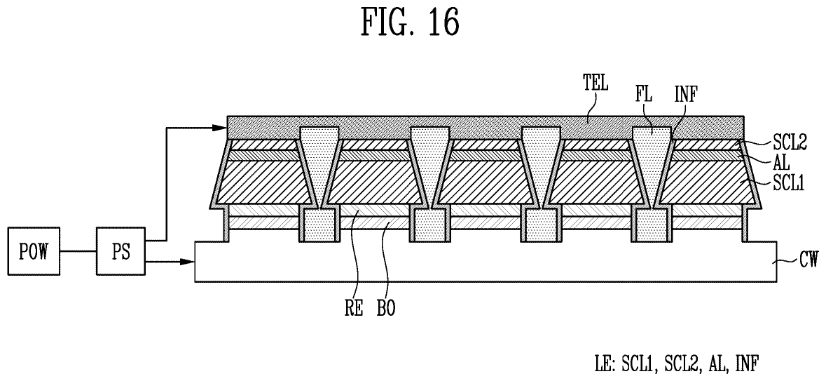

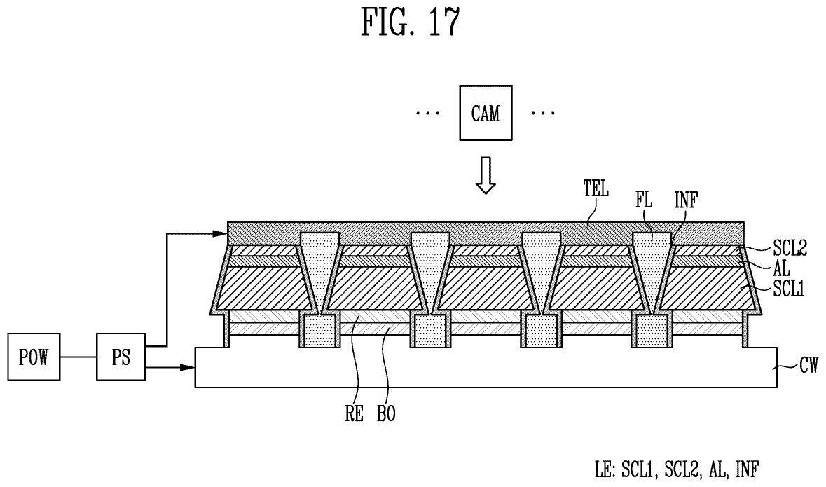

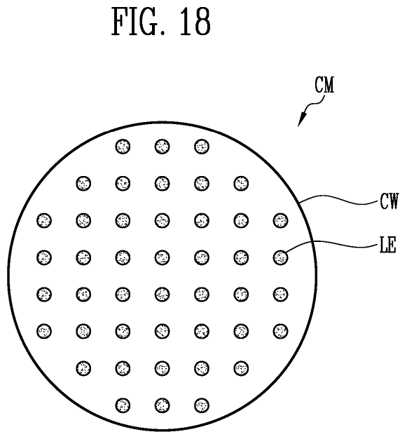

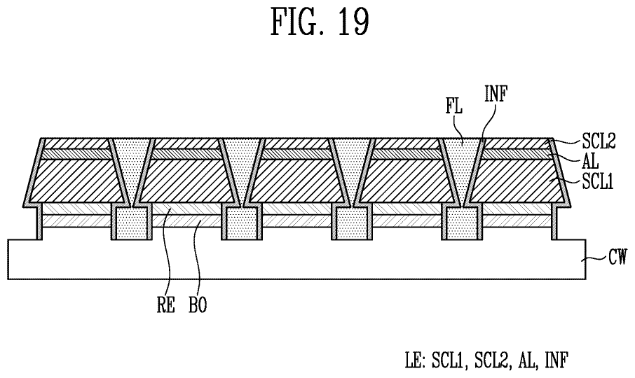

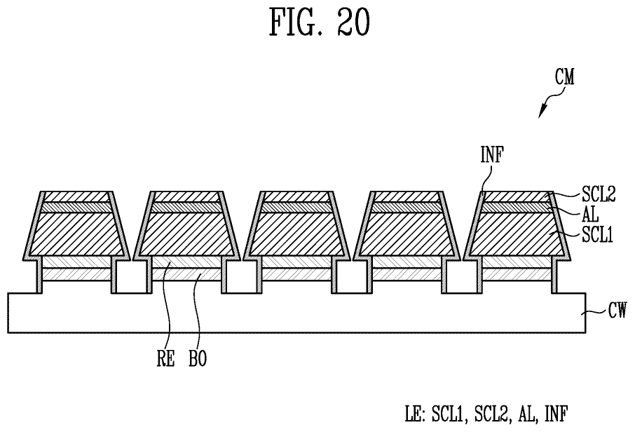

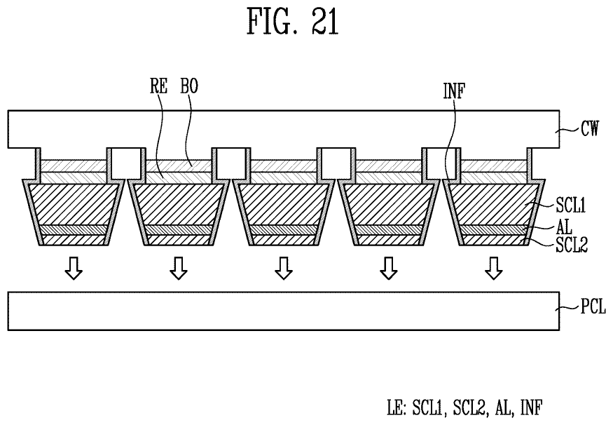

FIGS. 16 and 17 are schematic view illustrating process operations of the operation of inspecting the light-emitting elements in accordance with one or more embodiments of the present disclosure. FIG. 18 is a plan view illustrating a state in which the carrier module is viewed on a plane. FIGS. 19 and 20 a schematic views illustrating process operations of the operation of removing the planarization layer and the transparent electrode layer in accordance with one or more embodiments of the present disclosure. FIG. 21 is a view illustrating an operation of transferring the light-emitting elements in accordance with one or more embodiments of the present disclosure.

Referring to FIGS. 3, 16, and 17, in the operation S400 of inspecting the light-emitting elements, an inspection process on the light-emitting elements LE located on the carrier wafer CW may be performed.

In the operation S400 of inspecting the light-emitting elements, it may be inspected whether the light-emitting elements LE can normally emit light. For example, an electrical signal for allowing the light-emitting elements LE to emit light may be applied to the light-emitting element LE such that the light-emitting elements LE are inspected, and visual information, which may determine whether the light-emitting elements LE normally operate, may be acquired.

In accordance with one or more embodiments, a manufacturing apparatus (or inspecting apparatus) for performing the method of manufacturing the display device DD may include a power supply apparatus POW and a power application unit PS. In accordance with one or more embodiments, the manufacturing apparatus (or inspecting apparatus) for performing the method of manufacturing the display device DD may include a visual inspection apparatus CAM.

In accordance with one or more embodiments, the power supply apparatus POW may supply power to the power application unit PS. The power application unit PS may supply an electrical signal to both end portions of the light-emitting elements LE, and the light-emitting elements LE may emit light. The power application unit PS may supply the electrical signal to each of the light-emitting elements LE via the transparent electrode layer TEL and the carrier wafer CW. For example, the power application unit PS may supply a first electrical signal (e.g., a positive voltage or an anode signal) to the light-emitting elements LE via the carrier wafer CW. Accordingly, the first electrical signal for performing the inspection process may be supplied to the light-emitting elements LE. Also, the power application unit PS may supply a second electrical signal (e.g., a negative voltage or a cathode signal) to the light-emitting elements LE via the transparent electrode layer TEL. Accordingly, the second electrical signal for performing the inspection process may be supplied to the light-emitting elements LE.

In this operation, at least some of the light-emitting elements LE may emit light. In some embodiments, the light-emitting elements LE provided to be normally operable may normally emit light, and some of the light-emitting elements LE may not emit light when the some light-emitting elements LE have an abnormal state.

In this operation, the visual inspection apparatus CAM may acquire visual information on whether the light-emitting elements LE emit light. For example, the visual inspection apparatus CAM may include a camera and the like. However, the present disclosure is not limited thereto.

In some embodiments, the visual information acquired by the visual inspection apparatus CAM may include mapping information of the light-emitting elements LE and information on whether light is emitted for each position.

Referring to FIG. 18, when viewed on a plane, the light-emitting elements LE may be located on the carrier wafer CW to be spaced apart from each other. Mapping information on a position relationship in which the light-emitting elements LE are located may be previously set as shown in FIG. 18. Accordingly, based on the mapping information and the acquired visual information, it can be checked that light-emitting elements LE at corresponding positions emit light, and it can be checked that, light-emitting elements LE at other corresponding positions do not emit light as a process is performed. For example, position information of light-emitting elements LE (e.g., normal light-emitting elements) normally emitting light may be determined using n rows and m columns (n and m are integers of 1 or more). In addition, position information of light-emitting elements LE abnormally emitting light may be defined using x rows and y columns (x and y are integer of 1 or more).

In some embodiments, whether the light-emitting elements LE normally operate may be individually determined, and, in some embodiments, may be determined with respect to areas in which a ratio at which light-emitting elements LE abnormally operate is relatively high. For example, areas in which the light-emitting elements LE are arranged may include an abnormal area. The abnormal area may be an area in which light-emitting elements LE at a ratio (e.g., predetermined ratio) or higher do not emit light. In some embodiments, the ratio may be about 80% or the like, but the present disclosure is not limited thereto.

Referring to FIGS. 3, 19, and 20, in the operation S500 of removing the planarization layer and the transparent electrode layer, at least a portion of the transparent electrode layer TEL and the planarization layer FL of the carrier module CM may be removed. For example, referring first to FIG. 19, at least a portion of the transparent electrode layer TEL and the planarization layer FL may be removed through a Chemical Mechanical Polishing (CMP) process. However, this is merely illustrative, and any process through which a component located on the light-emitting elements LE can be removed is not limited thereto. Accordingly, only the planarization layer FL located in the spaces in the light-emitting elements LE are spaced apart from each other may remain.

After that, referring to FIG. 20, the remaining planarization layer FL may also be removed. In accordance with one or more embodiments, the remaining planarization layer FL may be removed through a partial etching process. In accordance with one or more other embodiments, the remaining planarization layer FL may be removed as laser is irradiated onto the planarization layer FL. The light-emitting element LE may be protected by the protective layer INF located on the light-emitting elements LE. For example, the protective layer INF may be made of an element having a very low absorption rate with respect to the laser. Accordingly, in this operation, the light-emitting elements LE may not be damaged and/or removed due to the protective layer INF.

In some embodiments, the method of manufacturing the display device DD may further include an operation of repairing the light-emitting elements LE. For example, at least some of light-emitting elements LE (e.g., abnormal light-emitting elements) determined/checked not to operate normally may be repaired. Accordingly, the light-emitting elements LE that otherwise abnormally operate (e.g., light-emitting elements LE that are abnormal, or that do not normally operate) may be provided as light-emitting elements LE that are normally operable.

In this operation, a repair process on the light-emitting elements LE may be performed. The repair process may be performed before the light-emitting elements LE are transferred onto a pixel circuit layer PCL (see FIG. 21), which will be described later. That is, the repair process may be performed after the operation of removing the transparent electrode layer TEL, and may be performed before an operation of transferring the light-emitting elements LE onto the pixel circuit layer PCL. Accordingly, unnecessary process cost may not be consumed.

Referring to FIG. 21, in some embodiments, the method of manufacturing the display device DD may further include an operation of transferring the light-emitting elements LE. For example, in this operation, the light-emitting elements LE may be transferred onto the pixel circuit layer PCL. In this operation, as the carrier wafer CW is moved, the light-emitting elements LE may be located on the pixel circuit layer PCL. In some embodiments, separate electrodes may be provided on the pixel circuit layer PCL, and the light-emitting elements LE may be arranged on the electrodes. After that, in one or more embodiments, the carrier wafer CW may be removed. Accordingly, the light-emitting element LE may be electrically connected to a pixel circuit included in the pixel circuit layer PCL to emit light. After that, an upper member, such as a window, may be located above the light-emitting elements LE, and the display device DD may be provided.

In accordance with one or more embodiments of the present disclosure, the inspection process may be performed before the light-emitting elements LE are transferred onto the pixel circuit layer PCL. Experimentally, when the inspection process is performed after the light-emitting elements LE are transferred on the pixel circuit layer PCL, the level of process difficulty may be excessively high. For example, when the inspection process is performed after the light-emitting elements LE are transferred on the pixel circuit layer PCL, it may be suitable to place pins for supplying an electrical signal respectively to one end portions of the light-emitting elements LE. Although the pins are to be electrically in contact with the end portions of the light-emitting elements LE, the pins may not be in contact with end portions of some light-emitting elements LE. In addition, it may be difficult for the repair process to be suitably performed on light-emitting elements LE having the abnormal state, and process cost may be increased.

However, a transparent electrode assembly (TEA) is provided, so that the inspection process can be performed before the light-emitting elements LE are transferred onto the pixel circuit layer PCL. Accordingly, the repair process can be more optimally performed, and process facilities can be simplified, thereby improving the reliability of processes.

In accordance with the present disclosure, there can be provided a method of manufacturing a display device and a display device, in which a defect rate of a light-emitting element is decreased, so that process efficiency can be improved.

In accordance with the present disclosure, there can be provided a method of manufacturing a display device and a display device, in which an inspection process of a light-emitting element can be suitably performed.

A display device according to an embodiment is applicable to various types of electronic devices. In an embodiment, an electronic device includes the above-described display device and may further include other modules or devices having additional functions in addition to the display device.

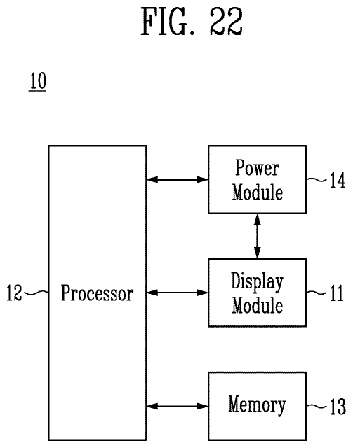

FIG. 22 is a block diagram of an electronic device according to an embodiment. Referring to FIG. 22, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

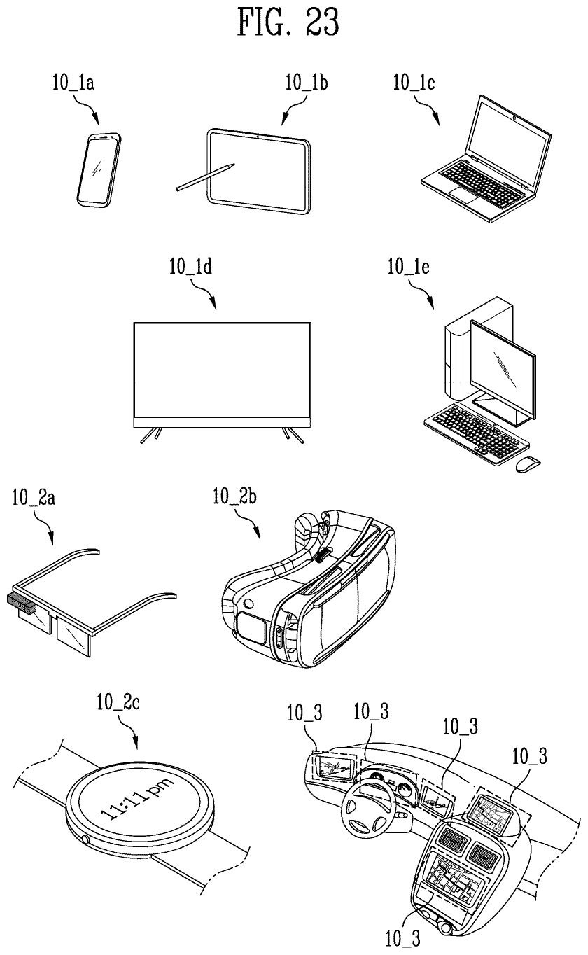

FIG. 23 shows schematic views of various embodiments of an electronic device.

Referring to FIG. 23, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment(s) may be used singly or in combination with features, characteristics, and/or elements described in connection with other embodiments, unless otherwise specifically indicated. Accordingly, it will be understood by those of skill in the art that various changes in form and details may be made without departing from the spirit and scope of the present disclosure as set forth in the following claims, with functional equivalents thereof to be included therein.

What is claimed is:

1. A method of manufacturing a display device, the method comprising:
providing a carrier module comprising a carrier wafer and light-emitting elements;
forming a planarization layer between the light-emitting elements;
forming a transparent electrode layer on the planarization layer;
inspecting the light-emitting elements; and
removing the planarization layer and the transparent electrode layer.

2. The method of claim 1, wherein the providing of the carrier module comprises:
forming a photoresist layer at an upper end of the light-emitting elements;
forming a protective layer on the light-emitting elements; and
removing the photoresist layer.

3. The method of claim 2, wherein the protective layer comprises a dielectric material.

4. The method of claim 1, wherein the removing of the planarization layer comprises removing at least a portion of the planarization layer such that an upper end of the light-emitting elements is exposed.

5. The method of claim 4, wherein the planarization layer comprises photosensitive polyimide.

6. The method of claim 4, wherein the forming of the transparent electrode layer on the planarization layer comprises using an ink-jet printing process.

7. The method of claim 6, wherein the transparent electrode layer contacts the upper end of the light-emitting elements.

8. The method of claim 1, wherein the transparent electrode layer comprises a carbon nano tube or a silver nano wire.

9. The method of claim 1, wherein the inspecting of the light-emitting elements comprises supplying a voltage to the carrier wafer and the transparent electrode layer such that power is supplied to the light-emitting elements.

10. The method of claim 9, wherein the inspecting of the light-emitting elements comprises acquiring visual information comprising mapping information of the light-emitting elements and indicating that at least some of the light-emitting elements emit light.

11. The method of claim 1, wherein the removing of the planarization layer and the transparent electrode layer comprises removing at least a portion of the planarization layer and the transparent electrode layer after the inspecting.

12. The method of claim 11, wherein the removing of the at least the portion of the planarization layer and the transparent electrode layer comprises a Chemical Mechanical Polishing (CMP) process.

13. The method of claim 11, wherein the removing of the planarization layer and the transparent electrode layer further comprises removing a remaining portion of the planarization layer.

14. The method of claim 13, wherein the removing of the remaining portion of the planarization layer comprises an etching process.

15. The method of claim 13, wherein the removing of the remaining portion of the planarization layer comprises removing the transparent electrode layer by irradiating laser onto the transparent electrode layer.

16. The method of claim 15, further comprising:
repairing at least one of the light-emitting elements; and
transferring the light-emitting elements onto a pixel circuit layer.

17. The method of claim 16, wherein the transferring of the light-emitting elements onto the pixel circuit layer comprises removing the carrier wafer, and placing the light-emitting elements on the pixel circuit layer.

18. A electronic device manufactured by the method of claim 1.

19. The electronic device of claim 18, wherein the light-emitting elements comprise a micro light-emitting diode (LED).

20. A visual inspection apparatus for the inspecting the light-emitting elements in the method of claim 1, the visual inspection apparatus being above the carrier module to acquire visual information through light emitted by at least some of the light-emitting elements.
